(19) United States
(12) Patent Application Publication
(10) Pub. No.: US 2006/0270252 A1
(43) Pub. Date: Nov. 30, 2006

(54) Electrical connection box

(75) Inventors: Haruhiro Muto, Incheon (KR); Hiroyuki Nakata, Mie (JP); Kim Sung Dam, Incheon (KR)

Correspondence Address: OLIFF & BERRIDGE, PLC, P.O. BOX 19928, ALEXANDRIA, VA, 22320, US

(73) Assignees: SUMITOMO WIRING SYSTEMS, LTD., Mie (JP); KYUNGSHIN INDUSTRIAL CO., LTD., Incheon (KR)

(21) Appl. No.: 11/442,168

(22) Filed: May 30, 2006

(30) Foreign Application Priority Data
May 27, 2005 (JP) 2005-155682

(51) Int. Cl. H05K 1/00

(52) U.S. Cl. 439/76.2

(57) ABSTRACT

An electrical connection box comprises: a stud bolt comprising a head portion having a rectangular shape where a short side D1 has; and a shaft portion having a center; a terminal; and a housing. The housing comprises a recess potion fixing the head portion; and an outer periphery holding portion. The recess portion has a long side serving as an attaching side edge intersecting with an extending side of the terminal. The terminal comprises: a bolt hole through which the shaft portion passes to be fastened by a nut; and a horizontal portion extending from an outer end edge of the housing to a side of the stud bolt. The horizontal portion is connected to a wire distal end. A dimension of the outer periphery holding portion from the outer end edge is T1. A dimension L1 from the outer end edge to the center is set to (D1/2)+T1.

### CROSS-REFERENCE TO RELATED APPLICATION

This application is based on and claims the benefit of priority from the prior Japanese Patent Application No. 2005-155682, filed on May 27, 2005; the entire contents of which are incorporated herein by reference.

### TECHNICAL FIELD

The present invention relates to a electrical connection box mounted on an automobile, in details, relates to a electrical connection box in which a head portion of a stud bolt is fixed to a housing of the electrical connection box and a shaft portion thereof is projected, and the shaft portion is made to pass through a bolt hole of a bolt fastening terminal connected to a wire terminal to be fastened to be fixed by a nut, space saving formation of a region of attaching the stud bolt and small-sized formation of the electrical connection box are achieved by improving a shape of the head portion of the stud bolt and a fixing portion on a side of the housing.

### BACKGROUND

According to an electrical connection box, a relay box or the like mounted to an automobile, in order to supply power source from a battery, a bolt fastening terminal of a battery terminal or the like connected to a distal end of a power source line is fitted to a shaft portion of a stud bolt connected to a bus bar arranged at inside of the electrical connection box and is fastened by a nut. For example, as shown by FIG. 6, a shaft portion 3a projected upward of a stud bolt 3 fixed to a housing 2 of a electrical connection box 1 is made to pass through a shaft hole of a bus bar 4 constituting an inner circuit of the electrical connection box 1 to be set thereby. On the other hand, an L-like terminal 5 connected to a front end of a power source line w is attached from an outer peripheral face over to an upper face of the housing 2, the shaft portion 3a of the stud bolt 3 is made to pass through a shaft hole 5b of a horizontal portion 5a disposed on an upper face side of the housing and a nut 6 is fastened thereto from an upper side by an impact wrench. (Refer to JP-A-9-306561)

When the wire distal end terminal and the bus bar are electrically connected by using the stud bolt and the nut as described above, as shown by FIG. 7, FIG. 8, normally, a head portion 3b of the stud bolt 3 used is constituted by a sectional shape of a square having one side of D2. As shown by FIG. 8, the head portion 3b is press-fitted to be fixed to a recess portion 2a in a shape of a square formed at an upper face of the housing 2. An outer peripheral portion of the recess portion 2a needs to be provided with an outer periphery holding portion 2b having a minimum width T1 or larger capable of withstanding impact generated in fastening the nut by the impact wrench. The width T1 of the outer periphery holding portion 2b is a previously rectified width.

Therefore, it is necessary to set a center position of the stud bolt 3 by constituting a minimum dimension by (D2/2)+T1 from an outer peripheral end 2e of the housing 2 of the electrical connection box.

In other words, it is necessary to separate the outer peripheral end 2e of the housing 2 by (D2/2)+T1 or larger from the center position of the stud bolt 3. Therefore, small-sized formation of the housing cannot be achieved by reducing the dimension from the center position of the stud bolt to an outer peripheral edge of the housing by less than (D2/2)+T1 to constitute a large bottle neck in view from small-sized formation of the electrical connection box and reduced formation of a space of installing the electrical connection box.

According to the terminal 5 connected to the wire distal end, as shown by FIG. 9, a length of the horizontal portion 5a becomes a dimension Lx constituted by summing up a dimension from a position 5c brought into contact with an outer peripheral edge of the housing to a center of the bolt hole 5b (D2/2)+T1 and a necessary minimum clearance d from the outer peripheral edge of the housing.

That is, Lx=(D/2)+T1+d to pose a problem that also the terminal 5 cannot be downsized.

### SUMMARY

The invention has been carried out in view of the above-described problem. According to an aspect of the invention, an electrical connection box can be downsized by setting a dimension from a position of fixing the stud bolt 3 to an outer peripheral edge of a housing. According to another aspect of the invention, a terminal of a wire distal end attached to a stud bolt is downsized.

According to another aspect of the invention, an electrical connection box comprises: a stud bolt comprising: a head portion having a rectangular shape in a cross section where a short side “D1” and a long side “D2” have; and a shaft portion having a center which coincides with a center of the head portion in the rectangular shape; a terminal having a L-like shape in cross section; and a housing. The housing comprises a recess potion which fixes the head portion of the stud bolt by press-fitting so as to erect the shaft portion of the stud bolt; and an outer periphery holding portion. The recess portion has a long side as an attaching side edge which intersects with a extending side of the terminal. The terminal comprises: a bolt hole through which the shaft portion of the stud bolt passes to be fastened by a nut; and a horizontal portion extending from an outer end edge of the housing to a side of the stud bolt. The horizontal portion is connected to a wire distal end. A dimension of the outer periphery holding portion from the outer end edge of the housing is a minimum dimension T1. A dimension L1 from the outer end edge of the housing to the center of the head portion of the stud bolt fixed to the recess portion is set to (D1/2)+T1.

### BRIEF DESCRIPTION OF THE DRAWINGS

These and other objects and advantages of this invention will become more fully apparent from the following detailed description taken with the accompanying drawings in which:

FIG. 1 is a sectional view of a main portion of a electrical connection box according to an embodiment;

FIG. 2 is a plane view of FIG. 1;

FIG. 3 is a sectional view taken along a line A-A of FIG. 2.

FIG. 4A is a plane view of a stud bolt, and FIG. 4B is a front view thereof;

FIG. 5 is a view showing a relationship of positions and dimensions of the stud bolt and an L-like terminal;

FIG. 6 is a perspective view of an electrical connection box according to a related art;

FIG. 7 is a perspective view of a stud bolt according to the related art;

FIG. 8 is a plane view showing a state of fixing a head portion of the stud bolt of the background art to a housing recess portion; and

FIG. 9 is a plane view of an L-like terminal fixed to the stud bolt of FIG. 8.

### DESCRIPTION OF THE EMBODIMENTS

Embodiment will be explained in reference to the drawings as follows.

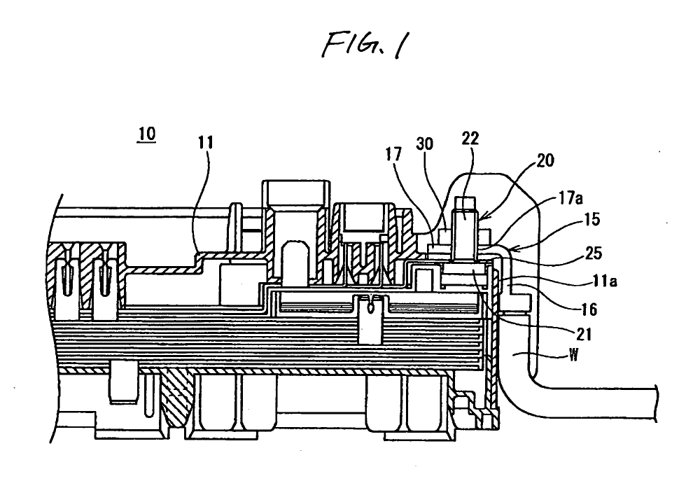

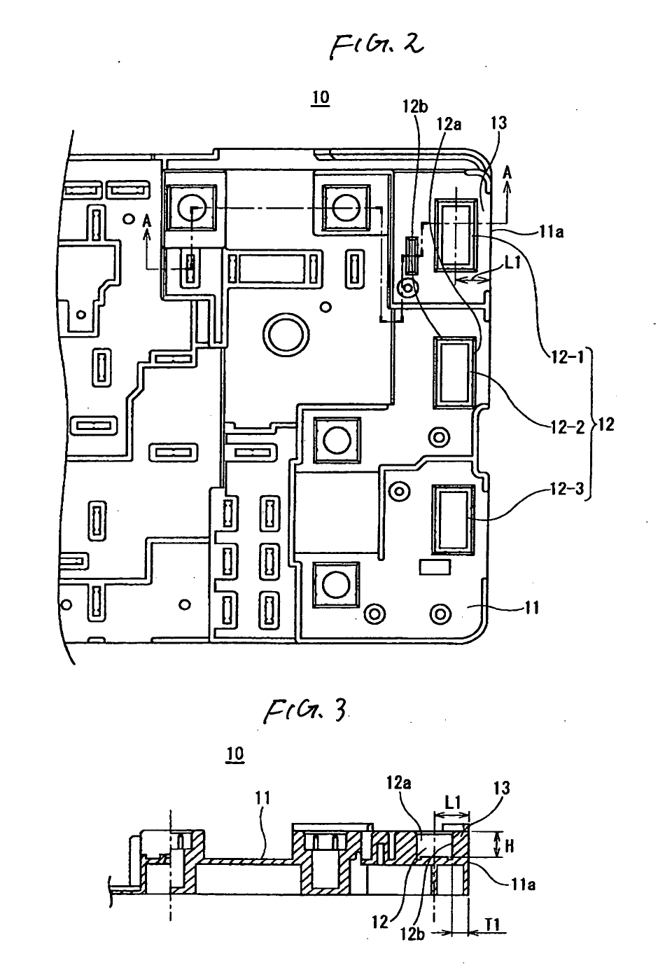

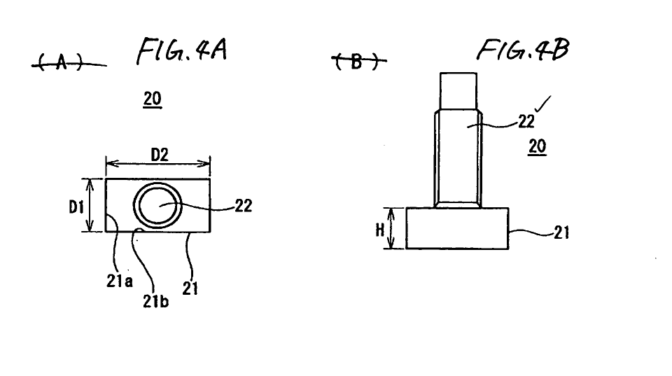

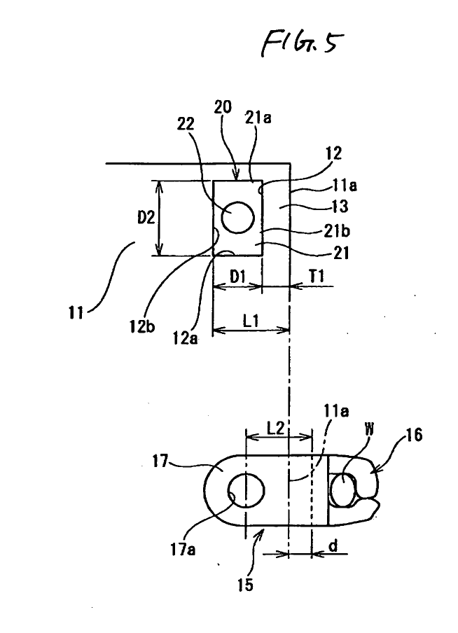

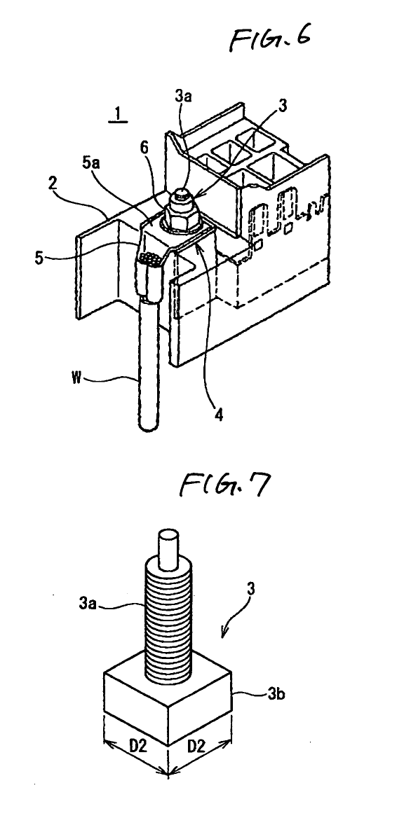

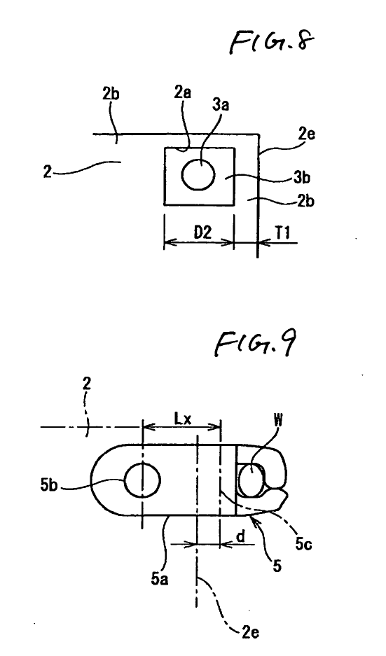

FIG. 1, FIG. 2 show a main portion of an electrical connection box 10 mounted to an automobile.

A housing 11 of the electrical connection box 10 is provided with recess portions (12-1, 12-2, 12-3) for press-fitting head portions of three stud bolts at an upper face 11b along one side outer face 11a on a side of attaching an terminal 15 connected to a distal end of a power source line w as shown by FIG. 3. The terminal 15 has a L-like shape in cross section. The recess portion 12 has a rectangular shape, a long side 12a thereof is a side in parallel with the outer face 11a, a short side 12b thereof is along a direction orthogonal thereto, and a depth H thereof is made to substantially coincide with a thickness of a head portion 20a of a stud bolt 20.

A dimension of an outer periphery holding portion 13 between an end edge of the recess portion 12 on a side of attaching the L-like terminal and the housing outer face 11a is designated by notation T1. The dimension T1 is a minimum dimension capable of withstanding an impact load when a nut 30 is fastened to the stud bolt 20 by an impact wrench, and the dimension T1 is previously rectified.

According to the stud bolt 20 for press-fitting to fix the head portion 21 to the recess portion 12 of the housing 11, a head portion 21 has a rectangular shape in a section thereof, a dimension of a short side 21a is designated by notation D1, a dimension of a long side 21b thereof is designated by notation D2, and the short side dimension D1 is made to be substantially a half of the long side dimension D2.

A shaft portion 22 is erected from the head portion 21 by making a center of the shaft portion 22 coincide with a center of the head portion 21.

According to dimensions of the recess portion 12 on a side of the housing 11 for press-fitting to fix the head portion 21 of the stud bolt 20, in order to press-fit to fix the head portion 21 thereto, the long side 12a of the recess portion 12 coincides with the long side dimension D2 of the stud bolt head portion, and the short side 12b coincides with the short side dimension D1 of the stud bolt head portion.

Therefore, a dimension L1 from the center of the stud bolt 20 to be press-fitted to fix to the recess portion 12 to the housing outer face 11a on the side of attaching the terminal is set to (D1/2)+T1.

According to the dimension L1, a dimension from a center position of the stud bolt 20 to the outer side face 11a of the housing 11 is reduced by an amount of a dimension of (D2−D1)/2 in comparison with a case of using the stud bolt having the head portion in the square shape of the background art.

The shaft portion 22 of the stud bolt 20 is set by being passed through a bolt hole 25a of a bus bar 25 included in the housing 11 and is mounted on an upper face of the head portion 21.

The terminal 15 electrically connected to the bus bar 25 comprises a vertical portion 16 serving as a wire pressedly attaching portion calked to be fixedly attached to the power source line w, and a horizontal portion 17 servings as an electrically connecting portion folded from an upper end of the vertical portion 16 and including a bolt hole 17a.

The vertical portion 16 is along the housing outer side face 11a to be spaced apart therefrom by a minimum clearance (d) therebetween, the horizontal portion 17 is extended from the housing outer side face 11a to a side of the stud bolt 20, the shaft portion 22 of the stud bolt 20 is passed through the bolt hole 17a to be outwardly fitted therewith to overlap the upper face of the bus bar 25.

According to the horizontal portion 17 of the terminal 15, a dimension L2 from the position folded from the vertical portion 16 to the center of the bolt hole 17a is set to L2=L1+d.

A length of the horizontal portion 17 of the terminal 15 can be shortened by the amount of the dimension of (D2−D1)/2 in comparison with the terminal connected to the stud bolt having the head portion in the square shape of the related art.

According to the electrical connection box 10 as shown by FIG. 1, the L-like terminal 15 at the distal end of the power source line w is wired to be along the outer side face 11a of the housing 11, and the shaft portion 22 of the stud bolt 20 is passed through the bolt hole 17a of the horizontal portion 17 of the terminal 15. Under the state, the nut 30 is fitted thereto from an upper side, the nut 30 is fastened to the shaft portion by an impact wrench (not illustrated), and the terminal 15 and the bus bar 25 are connected.

By changing the shape of the head portion 21 of the stud bolt 20 from the square shape to the rectangular shape in the section, the electrical connection box can be downsized by retreating an outer shape line of the housing of the electrical connection box more than in the background art. Therefore, in an automobile in which by a rapid increase in an electric equipment, a space for mounting the electric equipment tends to be gradually restricted, advantage of small-sized formation of the electrical connection box is considerable.

Further, it is not necessary to change a position of connecting the stud bolt to the bus bar, the outer shape of the housing can be reduced and therefore, an advantage is achieved in practical use thereof, further, also a degree of freedom of designing an inner portion of the housing can be promoted.

Further, also the L-like terminal connected to a wire can be downsized and a reduction in cost can be achieved by that amount.

According to the embodiments, the stud bolt is provided with the head portion in the rectangular shape by making the short side shorter and making the long side longer in accordance with a necessary torque resistance than those of the head portion in the square shape of the related art. As a result, the dimension of the head portion in the square shape of the related art from the center of the head portion of the stud bolt to the outer end edge of the housing can be reduced by an amount of a dimension of (D2−D1)/2.

According to the embodiments, as described above, by making a length of the long side of the head portion in the rectangular shape equivalent to a length of a side of the head portion in the square shape used in the background art, even in the case of the head portion in the rectangular shape, by constituting four corners thereof by right angle, the head portion in the rectangular shape press-fitted to fix to the recess portion of the housing can firmly be fixed without being turned around.

According to the embodiments, a dimension of the outer periphery holding portion of the recess portion from the recess portion of the housing to which the head portion in the rectangular shape is press-fitted to fix to the outer end edge of the L-like terminal attaching side is constituted by the dimension T1 and therefore, when the shaft portion of the stud bolt is made to pass through the bolt hole of the L-like terminal and the nut is fastened thereto by an impact wrench, the outer periphery holding portion can sufficiently withstand a loaded impact load.

Therefore, even when the head portion of the stud bolt is constituted not by the square shape of the background art but by the rectangular shape a section area of which is substantially halved, the head portion is provided with a turning stop function and can withstand the impact load.

According to the embodiments, by constituting the head portion of the stud bolt by a rectangle having the rectangular shape and disposing the short side in a direction of extending the L-like terminal, the dimension from the center of the head portion of the stud bolt to the outer end edge of the housing can be set by constituting a reference by the dimension of the short side.

On the other hand, an attaching side of the L-like terminal is not constituted by a direction of the long side of the head portion of the stud bolt and therefore, an occupied area of the electrical connection box is not enlarged by attaching the L-like terminal.

For example, when the head portion in the rectangular shape of the stud bolt is fixed to a corner portion of the upper face of the housing in the rectangular shape, the side of the short side of the head portion in the rectangular shape is made to coincide with the direction of extending the L-like terminal, an outer shape line in a state of arranging the L-like terminal at the outer face of the housing is restrained from being enlarged, the long side of the head portion in the rectangular shape is disposed in a direction orthogonal thereto in which the L-like terminal is not arranged, as a result, the occupied space in the state of attaching the L-like terminal to the electrical connection box is reduced.

According to the embodiments, the width T1 of the holding portion provided at the outer periphery of the recess portion of the housing to which the head portion in the rectangular shape is press-fitted to fix needs to be the widest since the impact load is applied to the side of extending the L-like terminal the most, and a width T2 of the holding portion on the side of the long side which is not attached with the L-like terminal can be set to be smaller than T1. Also in this respect, small-sized formation of the electrical connection box can be achieved by constituting the long side direction by the side which is not attached with the L-like terminal.

According to the embodiments, a short side D1 is in a range of ⅔ through ½ of a long side D2, preferably, about ½, and is a minimum dimension in a workable range.

About 0.5 mm can be ensured for a minimum dimension between the side of the short side and the shaft portion.

According to the embodiments, the terminal comprises: a vertical portion serving as a wire pressedly attaching portion; and the horizontal portion having the bolt hole and serving as an electric connecting portion which is folded from an upper end of the vertical portion. The vertical portion is along an outer peripheral face of the housing to be spaced apart from each other by a minimum clearance (d). The horizontal portion is extended from the outer end edge of the housing to a side of the stud bolt. A dimension L2 from a position of folding the horizontal portion to a center of the bolt hole is set to L2=L1+d.

As described above, also a length of the horizontal portion of the terminal connected to the wire can be shortened by the amount of the dimension (D2−D1)/2 in comparison with that of the case of connecting the head portion in the square shape of the related art to the stud bolt, and small-sized formation of the terminal can also be achieved.

According to the embodiments, the electrical connection box comprises a junction box or a relay box mounted to an automobile. The recess portions are aligned at an upper face of the housing along one face of an outer peripheral face of the housing to be spaced apart from each other by an interval. The stud bolts are press-fitted to fix to the recess portions. The shaft portions of the stud bolt are made to pass through a bolt hole of a bus bar included inside of the housing. The terminal of the wire distal end wired along an outer peripheral face of the housing is fastened to the stud bolt by the nut. The terminal and the bus bar are electrically connected.

According to the embodiments, the electrical connection box or the relay box is large-sized, particularly, when the electrical connection box is mounted to an engine compartment, a restriction of a mounting space at inside of the engine compartment is considerable and therefore, an advantage of capable of downsizing the electrical connection box is considerable.

As described above, in a structure of fastening to fix the terminal connected to the wire to the stud bolt the head portion of which is fixed to the housing of the electrical connection box by the nut, by constituting the section of the head portion of the stud bolt by the rectangular shape and making the short side coincides with the direction of extending the L-like terminal, the dimension from the position of fixing the stud bolt to the outer end edge of the housing on the side of attaching the L-like terminal can be reduced.

As a result, the housing of the electrical connection box can be downsized, further, even when the housing is downsized, it is not necessary to change the position of connecting the stud bolt and the bus bar at inside of the housing. Therefore, it is not necessary to change design of the bus bar or the like at inside of the housing, further, even when the design is changed, a degree of freedom of the design can remarkably be promoted. Further, small-sized formation of the L-like terminal connected to the wire side can be achieved.

What is claimed is:

1. An electrical connection box comprising:
a stud bolt comprising:
a head portion having a rectangular shape in a cross section where a short side “D1” and a long side “D2” have; and
a shaft portion having a center which coincides with a center of the head portion in the rectangular shape;
a terminal having a L-like shape in cross section, the terminal comprising:
a bolt hole through which the shaft portion of the stud bolt passes to be fastened by a nut; and
a horizontal portion extending from an outer end edge of the housing to a side of the stud bolt, the horizontal portion being connected to a wire distal end,
a housing comprising:
a recess potion which fixes the head portion of the stud bolt by press-fitting so as to erect the shaft portion of the stud bolt; the recess portion having a long side as an attaching side edge which intersects with a extending side of the terminal; and
an outer periphery holding portion,
wherein a dimension of the outer periphery holding portion from the outer end edge of the housing is a minimum dimension T1; and
wherein a dimension L1 from the outer end edge of the housing to the center of the head portion of the stud bolt fixed to the recess portion is set to (D1/2)+T1.

2. The electrical connection box according to claim 1, wherein the short side “D1” is in a range of ⅔ of the long side “D2” through ½ of the long side “D2”.

3. The electrical connection box according to claim 1, wherein the terminal comprises:
a vertical portion serving as a wire pressedly attaching portion; and
the horizontal portion having the bolt hole and serving as an electric connecting portion which is folded from an upper end of the vertical portion,
wherein the vertical portion is along an outer peripheral face of the housing to be spaced apart from each other by a minimum clearance (d),
wherein the horizontal portion is extended from the outer end edge of the housing to a side of the stud bolt, and
wherein a dimension L2 from a position of folding the horizontal portion to a center of the bolt hole is set to L2=L1+d.

4. The electrical connection box according to claim 1, wherein the electrical connection box comprises a junction box or a relay box mounted to an automobile,
the recess portions are aligned at an upper face of the housing along one face of an outer peripheral face of the housing to be spaced apart from each other by an interval,
the stud bolts are press-fitted to fix to the recess portions,
the shaft portions of the stud bolt are made to pass through a bolt hole of a bus bar included inside of the housing,
the terminal of the wire distal end wired along an outer peripheral face of the housing is fastened to the stud bolt by the nut, and
wherein the terminal and the bus bar are electrically connected.

5. The electrical connection box according to claim 1, wherein the minimum dimension T1 is set so as to withstand impact load generated when the nut is fastened.
